(19) United States
(12) Patent Application Publication
(10) Pub. No.: US 2024/0007044 A1
(43) Pub. Date: Jan. 4, 2024

(54) BIFACIAL PHOTOVOLTAIC MODULE, SINGLE AXIS SOLAR TRACKER AND OPERATING METHOD THEREOF

(71) Applicant: SOLTEC INNOVATIONS, S.L., Molina de Segura (ES)

(72) Inventor: José Alfonso TERUEL HERNÁNDEZ, Molina de Segura (ES)

(73) Assignee: SOLTEC INNOVATIONS, S.L., Molina de Segura (ES)

(21) Appl. No.: 18/036,886

(22) PCT Filed: Nov. 8, 2021
(86) PCT No.: PCT/EP2021/080905

§ 371 Date: May 14, 2023

(30) Foreign Application Priority Data
Nov. 13, 2020 (EP) 20382980.9
Feb. 19, 2021 (ES) U202130347

(51) Int. Cl. H02S 20/32; H01L 31/068

(52) U.S. Cl. CPC H02S 20/32; H01L 31/0684

(57) ABSTRACT

Solar trackers are designed to withstand high wind loads, eventually by oversizing the structure and incurring in higher material cost and rendering high costs scenarios when deploying solar trackers in solar fields. A solar tracker and a method for operating the solar tracker yields a solution highly structured solar trackers by providing a single horizontal axis solar tracker associated to at least one bifacial photovoltaic module. The single horizontal axis solar tracker has a bifacial photovoltaic module associated to the torque tube using a joint fixture along one of the sides of the bifacial solar module so that the solar module jointly moves when the torque tube rotates. The single horizontal axis solar tracker may be operating according to the time of the day consequently to the available sunlight, so that a face of the bifacial photovoltaic module associated to the torque tube is facing the sun.

### CROSS-REFERENCE TO RELATED APPLICATIONS

This application is a national stage under 35 U.S.C. § 371 of PCT patent application PCT/EP2021/080905 filed on 8 Nov. 2021, which is pending and which is hereby incorporated by reference in its entirety for all purposes. PCT/EP2021/080905 claims priority to European Patent Application 20382980.9 filed 13 Nov. 2020, which is hereby incorporated by reference in its entirety for all purposes. PCT/EP2021/080905 claims priority to Spanish Patent Application 0202130347 filed 19 Feb. 2021, which is hereby incorporated by reference in its entirety for all purposes.

### OBJECT OF THE INVENTION

The object of the invention generally pertains to the field of renewable energies.

A solar tracker for solar collectors for generating energy from the sun is hereby provided. In particular, the invention refers to a solar tracking method, by using a single horizontal axis solar tracker, for mitigating or reducing the effects of wind on a solar tracker or array of solar trackers deployed on a solar plant.

### BACKGROUND

Some solar collectors use a tracking system with which the collector can dynamically align the surface of the solar modules with the Sun and optimize the energy generated. If the collector is tracking the sun as it moves from east to west over the course of a day, the orientation of the collector can sometimes expose its structure to significant wind loads. As a result, the solar collector must be constructed with a more rigid structure and stronger supports, which increases the construction and/or installation costs of the collector. If the wind speed exceeds a threshold, the solar panel can even retreat into a congestion mode where suboptimal solar energy or no energy is detected. There is therefore a need for a solar collector that is less sensitive to wind loads to reduce the cost of the solar collector and to increase the time that the collector is actively tracking the sun.

Most of today's solar panels collect solar irradiance from only the front side of the panel, which faces the sun. Bifacial modules collect the light that enters from both the front and back sides of a solar panel. By converting both direct and reflected light into electricity, bifacial PV systems can generate more energy than a comparable monofacial system, depending on how and where the system is deployed. Even though bifacial cell technology has existed since it was invented in 1976 by Professor Antonio Luque and first manufactured by the company Isofoton in the early 80s, it has been hard to be commercially embraced due to the high production costs associated thereto. A drop in manufacturing costs, however, is now leading the solar industry to now consider the implementation of bifacial panels.

U.S. Pat. No. 8,324,496B1 discloses wind screens for reducing wind loading on one or more solar collectors are disclosed. The wind screens move with the solar collector as the collector tracks the sun in one or more dimensions. The wind screen pivotably connects to at least one solar panel of the collector. Another side of the wind screen may connect to the ground or to an adjacent collect, thus serving to divert wind over the collector. Wind screens may be made of various materials including rigid, flexible, or elastic materials and can change position, orientation, and/or effective length as the one or more collectors track the sun from East to West. In U.S. Pat. No. 8,324,496B1 one or more wind screens for shielding the solar collector from lateral winds. In some embodiments, the solar collector includes one or more solar panels that pivot about single axis to track the sun over the course of the day. The wind screen of U.S. Pat. No. 8,324,496B1 may comprise one or more screens that couple the outer edges of the panels to the ground to divert the wind over the collector. In some other embodiments, the solar collector includes an array of collectors in which solar units are arranged side-by-side. The wind screens then connect to adjacent solar collectors to provide a continuous surface across the array and inhibit wind from generating lift under any of the units. Of course, a combination of these ground-attached screens and cross-collector screens may be employed together to mitigate wind at the edges and interior of a solar collector array.

U.S. Pat. No. 9,347,692B2 discloses a system for providing solar energy collection with a modular design or array of solar energy collection devices or panels angled to the position of the sun. The solar collection systems devised in the invention have either a combination of fixed panels and tracking panels or only tracking panels, both kinds of panels converting sunlight incident upon them to electrical power. The tracking panels of the invention follow the daily movement of the sun to efficiently collect solar power from dawn to dusk. The invention includes systems for providing both single axis and dual axis solar tracking. The first axis of the system is used to track solar daily changes, the tracking panels adding power to the system when the sun is moving through zenith between approximately 10 AM to 2 PM. The shadowing of the tracking panels is minimal to zero at noon. The second axis of the system is used to adjust to solar seasonal changes by inclining the solar panel module or system to the appropriate angle. Both axes are driven by motors that are controlled by hardware and programmable software that seeks optimum angular positions both daily and seasonally. The system and software are designed to account for in site installation at any latitude to efficiently track the daily and/or seasonal positions. The systems in general are also designed to be sufficiently rugged to withstand forces of the elements such as wind, rain, etc., and to meet international and national building code specifications. In addition, the physical structure of the system is designed for ease of installation and maintenance because of its modular design. Such modular design of the solar panels of the invention allows connections to adjacent modules or arrays on a variety of sites such as residential roof tops, factory rooftops, large ground installations, on patio covers, car ports, parking lot shade structures etc.

WO2013021078 discloses a solar tracker comprising a base on which a solar panel is installed having first and second opposite ends which can be connected to said base by respective first and second mutually parallel axes by means of an automatic connection/disconnection device that connects the second end of the solar panel to the base at the same time that disconnects the first end of the solar panel of the base, and vice versa each time the solar panel reaches a position parallel to the base, so that the solar panel can pivot with respect to the base around said first axis when the first end is connected to the base and the second end is disconnected from the base and the solar panel can pivot relative to the base about said second axis when the second end is connected to the base and the first end is disconnected from the base. The solar tracker further comprises a lift mechanism connected to the solar panel in an intermediate region between said first and second ends and a lift/lower actuator operatively connected to move said lift mechanism and thereby pivot said panel alternately around the first axis and around the second axis passing through said position parallel to the base according to the relative movements of the sun. Thus, the lift/lower actuator and the lift mechanism are configured to pivot the solar panel between an elevated position and a position parallel to the base and the automatic on/off device is configured to reverse the tilt of the solar panel relative to the base each time the solar panel reaches the position parallel to the base and the lifting mechanism is actuated again to move the solar panel from the position parallel to the base towards the raised position.

Document US 20110061644 discloses a low-profile solar energy collecting system comprising a base for mounting the system on a suitable substrate and a plurality of solar panels arranged side by side on the base. A first group of solar panels are movable relative to a second group of solar panels to follow the relative movements of the sun during the day. The solar panels of the first group are arranged alternately with the solar panels of the second group. In one embodiment the solar panels of the second group are arranged stationary and, in another embodiment, they are movable relative to the solar panels of the first group. One drawback of this system is that at any given time only one group of solar panels, that is, only half of the solar panels receive the sun's rays under appropriate conditions.

Document CN 101098113 describes a solar tracker comprising a horizontal rotary support on which is installed a solar panel having a first lower end pivotally connected to the horizontal support by a horizontal axis. A first actuator drives rotational movements of the horizontal rotary support around a vertical axis to orient the solar panel in the east-west direction and a second actuator drives a lifting mechanism that pivots the solar panel with respect to the horizontal rotary support around said horizontal axis to orient the solar panel in the north-south direction according to the relative movements of the sun. One drawback of this solar tracker is that it needs two tracking mechanisms on two orthogonal axes, which is why it is complex and expensive.

While bifacial module technology increases power generation, there are some factors that may affect the rate of this increase. Among the most critical factors to consider when calculating bifacial module yield are module mounting height and albedo, or the fraction of light reflected by the surface. Module mounting height—The closer a bifacial PV array is to the ground or a roof surface, the less chance reflective light will reach the back of the array. A significant bifacial energy boost is possible, however, with a relatively modest height increase.

### DESCRIPTION

The object of the invention encompasses a solar tracker with a single horizontal axis for bifacial photovoltaic modules, hereinafter the solar tracker of the invention or the solar tracker.

The object of the invention provides a solution to the aforementioned problems. The object of the invention is a single axis tracker for bifacial modules providing the potential savings of a low-profile structure for solar tracking on a horizontal axis. It is understood that there will be significant savings in the use of structural material, usually steel, per peak power of installed photovoltaic modules. Thanks to the low profile of the solar tracker of the invention, wind resistance is reduced.

Being conceived solely for use with bifacial modules, the solar tracker of the invention is capable of making the most of bifacial solar modules; yielding a high power generation ratio per weight kilogram of material employed for manufacturing the structure. Bifacial solar modules with a remarkably high bifaciality value, such as HJTs, are preferred.

The solar tracker with a single horizontal axis associated to at least one bifacial photovoltaic module hereby proposed comprises an arrangement of landscape oriented bifacial photovoltaic modules attached to the axis of rotation, torque tube, so that one of the sides of the panel, preferably long sides, remain integral with the axis of rotation in the longitudinal direction, so that the bifacial modules are fixed in an unbalanced way, being at maximum torque when they are positioned aligned with the horizontal plane; hence, a cantilever equivalent to approximately to the width of the solar panels is defined thereby, being the standard width of solar modules set around 1 meter or 40 inches width.

The object of the invention is to be preferably deployed along with the solar module described in ES1243445, which priority is claimed disclosing a carrier frame for solar modules that is configured to be jointly fixed to the torque tube of a solar tracker in such a way that the frame, and consequently the photovoltaic module carried by the frame, jointly moves as the torque tube rotates. Hence the resulting solar module moves when the torque tube jointly travels with said frame jointly attached thereby.

The torque tube of the solar tracker of the invention would be located at a height with respect to the ground which would be equal to the minimum allowed in this type of solar plants between panels and ground, according to regulations or customer specification lower than than 1.5 m (typically around 0.5 meters or 20 inches).

The foundation to the ground of this solar tracker could be done in different ways, being able to use cold formed profile drives, extruded profiles, concrete footings, screws or any other alternative already on the market for solar trackers of a horizontal axis.

In a second aspect of the object of the invention a method for operating the solar tracker of the invention is provided.

### DESCRIPTION OF THE INVENTION

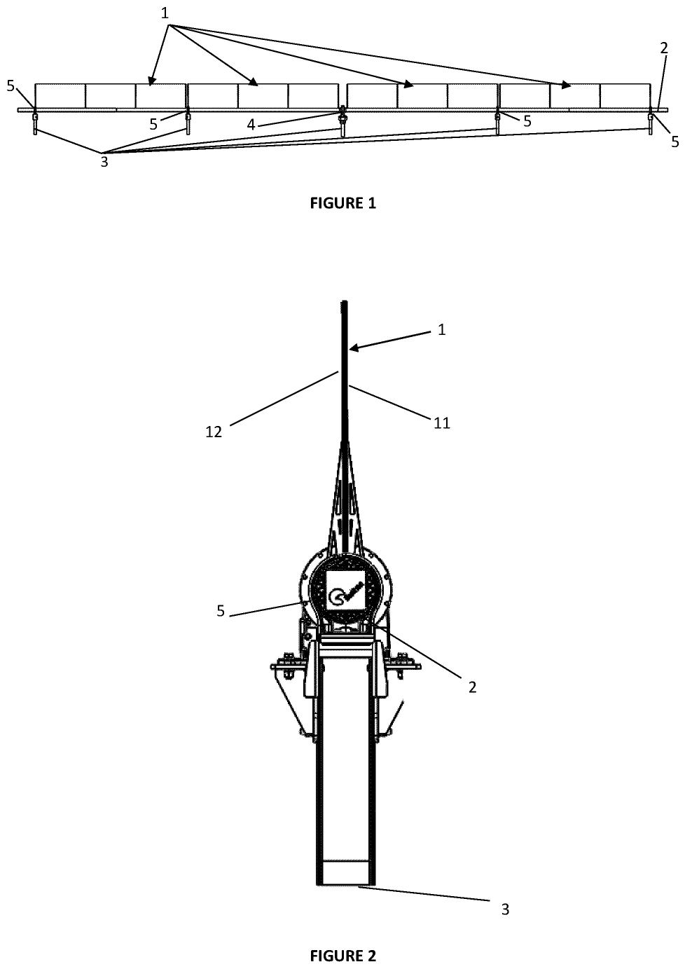

FIG. 1—Shows a side view of solar tracker of the invention wherein the solar modules are in a vertical position, at a 0 degrees angle and the modules are arranged in landscape orientation.

FIG. 2—Shows a front view of solar tracker of the invention wherein the solar modules are in a vertical position, at a 0 degrees angle.

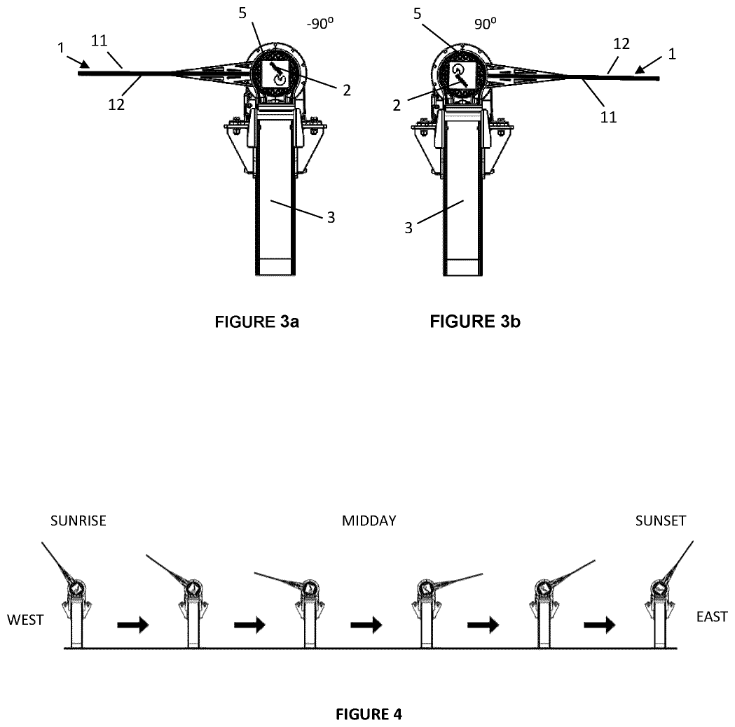

FIG. 3—Shows a front view of solar tracker of the invention wherein the solar modules are in a horizontal position, at a −90 degrees angle (FIG. 3a) and 90 degrees angle (FIG. 3b).

FIG. 4—Shows a front view diagram depicting a standard tracking procedure for a day.

FIG. 5—Shows a diagram depicting an array of solar trackers wherein the solar modules is set to a horizontal defensive position, facing the wind direction.

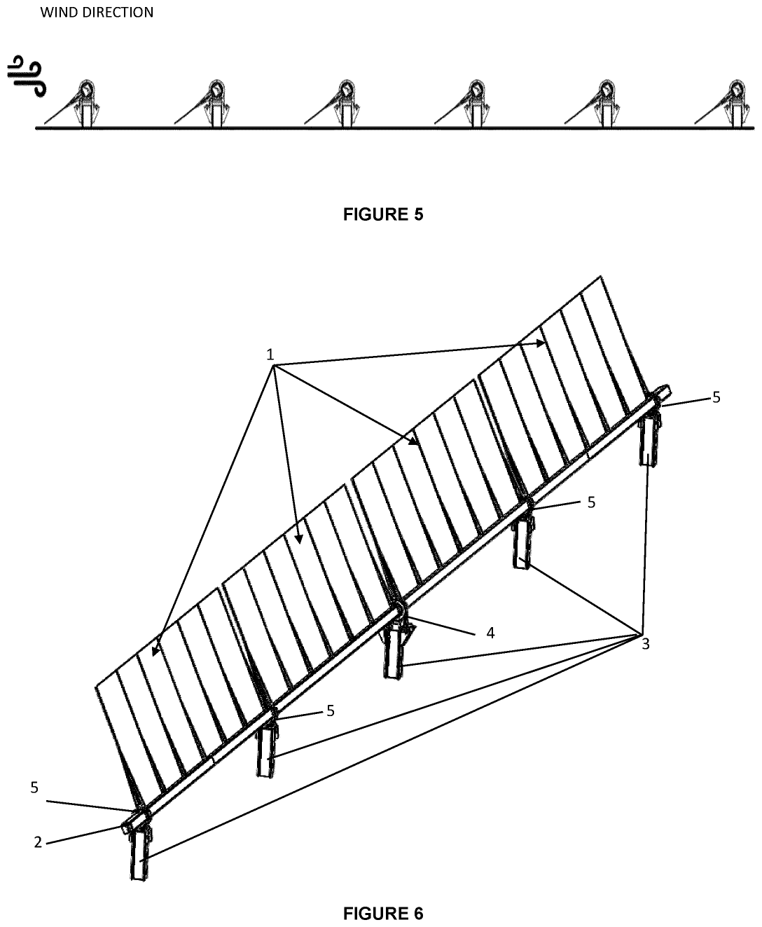

FIG. 6.—Shows a 3D representation of the object of the invention wherein the torque tube is driven by an actuator arranged on the central post and the modules are arranged in portrait orientation.

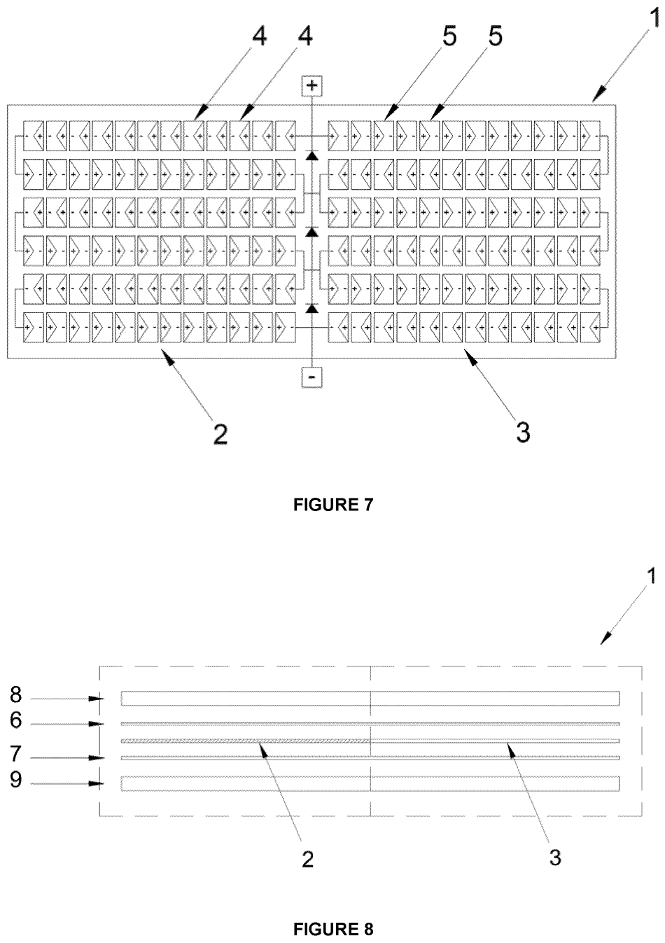

FIG. 7.—Shows a schematic representation of a preferred embodiment of a photovoltaic module according to the invention, with split cells wherein, for the sake of simplicity, a first side is shown on the left and a second side, opposite to the first side, is shown on the right.

FIG. 8.—Shows a cross-section side view of the module of FIG. 1.

### DETAILED DESCRIPTION

In a preferred embodiment of the object of the invention a single horizontal axis solar tracker associated to at least one bifacial photovoltaic module (1) is provided as the one shown in FIGS. 1-3. For this preferred embodiment and in a non-limiting manner, the single horizontal axis solar tracker associated to at least one bifacial photovoltaic module (1) of the invention comprises said bifacial photovoltaic module (1) attached to the torque tube (2) by articulated joints, preferably by means of bearings (5). The solar tracker of the invention comprises the torque tube (2) supported by a post (3) fixed to the ground, consequently the solar tracker is fixed to the ground by means of posts (3) holding the torque tube (2); hence, any reference to angles is to be understood as being referred to the longitudinal axis of said posts (3).

The single horizontal axis solar tracker of the invention comprises the bifacial photovoltaic modules (1), preferably rectangular, with one of its sides, preferably a long one, jointly attached to the torque tube (2) so that one of the long sides of the panel remain integral with the torque tube (2) in the longitudinal direction, wherein the bifacial photovoltaic module (1) is fixed in an unbalanced way, being at maximum torque when the bifacial photovoltaic module (1) is positioned aligned with their horizontal plane; defining a cantilever preferably equivalent to approximately to the width of the bifacial photovoltaic module (1). In other words, the bifacial photovoltaic module (1) is associated to the torque tube (2) by means of a joint fixture along one of the sides of the bifacial solar module in such way that the solar module jointly moves when the torque tube (2) rotates.

The solar tracker of the invention presents the torque tube (2) having a round section (as per FIG. 2) or a square section (as per FIG. 6) and arranged at a height above ground of around 0.5 meters or 20 inches having the bifacial photovoltaic module (1) a height of around 1 meter or 40 inches, thus rendering a total height of around 1.5 meters or 5 feet, allowing an easy deployment of the solar tracker without heavy and/or special machinery.

In a preferred embodiment of the object of the invention the torque tube (2) is driven by a motor or actuators (4) as in FIG. 6, this allows a controlled movement of the bifacial photovoltaic module (1).

The method of the invention basically comprises gradually positioning, driven by the torque tube (2), the bifacial photovoltaic module (1) in such a way that the front face (11) of the bifacial photovoltaic module (1) faces the sun from dawn to noon and that the back face (12) of the bifacial photovoltaic module (1) faces the sun from noon to sunset as per FIGS. 3a and 3b.

Using a clock hands pattern, the method of the invention may be described in view of FIG. 4 as follows:
From dawn to noon, the solar tracker of the invention would start solar tracking mode in such a way that a front face (11) of the bifacial photovoltaic module (1) faces the sun, being gradually positioned at −90° with respect to the longitudinal axis of the post (3) at noon, shifting from a close to 12 h to a close to 9 h position of an hour hand in a watch. Rendering the situation depicted by FIG. 3a.
After noon, it is required a movement from west to east so that the bifacial photovoltaic module (1) has a back face (12) of the bifacial photovoltaic module (1) facing the sun. With this movement the panels shift from close to 9 h to a close to 3 h position of an hour hand in a watch.
Gradually positioning, from noon to sunset, the bifacial photovoltaic module (1) with its back face facing the sun to a position of 90° with respect to the longitudinal axis of the post (3), shifting from a close to 3 h to a close to 12 h position of an hour hand in a watch. Rendering the situation depicted by FIG. 3b.

Additionally, the method of the invention may comprise a backtracking operating mode, so that to avoid shadowing effects, in this preferred embodiment, the progressive movement of the bifacial photovoltaic module (1) driven by the torque tube (2) is limited by a limited angular range previously defined. This range will depend on the size and orientation of the bifacial photovoltaic module (1) over the torque tube (2) and the height of the torque tube (2) above the ground level. For a typical landscape orientation of standard modules and 20 inches or 0.5 meters of torque tube (2) height, the limited angular range would be 240 degrees or +/−120 from the vertical.

In case of high-speed winds, the bifacial photovoltaic module (1) can be placed in a horizontal position, essentially orthogonal in respect to the post (3), and even exceed that position to even touch the ground, as depicted in FIG. 5.

Furthermore, the method of the invention may further envisage arranging the bifacial photovoltaic module (1) in an essentially horizontal position in case high-speed winds are determined or at a minimum angular position to reach the angular limit in case high-speed winds are determined. This positioning embraces operating the solar tracker so the bifacial photovoltaic module (1) is moved to the east in case wind direction is determined to come mainly come from east or to the west in case wind direction is determined to mainly come from west.

Thanks to the low profile of this type of solar tracker, considerable savings in the use of material (mainly steel) are estimated, mainly due to its limited exposure to the wind. A detailed structural study is necessary to be able to evaluate the potential savings in the most key elements: torque tube (2), drives and actuators.

The photovoltaic module (1) comprises, as shown on FIG. 7, a first module face (12), oriented according to a first direction and a second module face (13), opposite to the first module face (12) and, therefore, oriented according to a second direction, opposite to the first direction. A plurality of bifacial cells (4, 5) are mounted in the module (1), each of which comprises a first cell face, with a greater pick-up capacity, and a second cell face, with a lower pick-up capacity. Advantageously, the bifacial cells (14, 15) comprise first bifacial cells (14), oriented with a first cell face towards the front direction, and a second cell face towards the rear direction; and second bifacial cells (15), oriented with the second cell face towards the front direction and the first cell face towards the rear direction. One or more first internal chains connect the first bifacial cells (4) in series, while one or more second internal chains connect the second bifacial cells (5) in series, the first internal chain and the second internal chain being connected to each other in parallel, to generate the output of the photovoltaic module (1).

The first bifacial cells (14) and the second bifacial cells (15) are preferably of the type called “split cells” (known interchangeably in English as “half-cell” or “half-cut”). In this case, the use of several first and second internal chains is particularly advantageous. Each group of first bifacial cells (4) and second bifacial cells (5)—in your case, each of the first and second internal chains—can have its bifacial cells (4, 5) grouped into one or more respective first zones and second zones, to facilitate the connections between the bifacial cells (4, 5) of each internal chain. Alternatively, the bifacial cells (4, 5) can be uniformly distributed along the module (1), to gain robustness against shadow and/or cloud situations.

The first module face (12) and the second module face (13) may incorporate a transparent cover (18, 9), such that, for example, made of tempered glass, to protect the bifacial cells (14, 15) weather conditions. For better performance, it is preferred that the covers have some anti-reflective treatment. As shown in FIG. 8, the module (1) comprises two encapsulating sheets (16, 17) so the bifacial cells (14, 15) are protected by forming an encapsulation; furthermore, the two covers (18, 19) may be provided with an antireflection treatment, between which the encapsulation is enclosed.

1.-21. (canceled)

22. A solar tracking method using a single horizontal axis solar tracker,
the single horizontal axis solar tracker associated to at least one bifacial photovoltaic module, the single horizontal axis solar tracker comprising:
an arrangement of bifacial photovoltaic modules fixed to a torque tube, of the solar tracker, the torque tube being supported by several posts by articulated joints and said posts fixed to the ground, and
the bifacial photovoltaic module being associated to the torque tube by a joint fixture along one of the sides of the bifacial solar module in such a way that the solar module jointly moves when the torque tube rotates;
the method comprising the step of:
operating the torque tube for gradually positioning the bifacial photovoltaic module in such a way that either the front face or the back face of the bifacial photovoltaic module faces the sun from dawn to noon.

23. The method of claim 22, further comprising the step of:
operating the torque tube for gradually positioning the bifacial photovoltaic module in such a way that either the front face or back face of the bifacial photovoltaic module faces the sun from noon to sunset.

24. The method of claim 23, further comprising the step of:
operating the torque tube for arranging the bifacial photovoltaic module essentially orthogonal in respect to the post in case high-speed winds are determined.

25. The method of claim 24, further comprising the step of:
operating the torque tube for positioning the bifacial photovoltaic module to an angular limit towards the east in case wind direction is determined to mainly come from east.

26. The method of claim 24, further comprising the step of:
operating the torque tube for positioning the bifacial photovoltaic module to an angular limit towards the west in case wind direction is determined to mainly come from west.
